(19) United States
(12) Patent Application Publication
(10) Pub. No.: US 2025/0048844 A1
(43) Pub. Date: Feb. 6, 2025

(54) ADVANCED PATTERNING OLED OVERHANG SUB-PIXEL CIRCUIT AND PATTERNING METHOD

(71) Applicant: Applied Materials, Inc., Santa Clara, CA (US)

(72) Inventors: Jungmin LEE, Santa Clara, CA (US); Dieter HAAS, Santa Clara, CA (US); Yu-Hsin LIN, Zhubei City (TW); Chung-chia CHEN, Hsinchu City (TW); Ji Young CHOUNG, Hwaseong-si (KR)

(21) Appl. No.: 18/771,267

(22) Filed: Jul. 12, 2024

Related U.S. Application Data
(60) Provisional application No. 63/516,755, filed on Jul. 31, 2023.

(51) Int. Cl. H10K 59/122; H10K 59/12

(52) U.S. Cl. CPC H10K 59/122; H10K 59/1201

(57) ABSTRACT

Embodiments described herein relate to a method of forming a sub-pixel. The method includes depositing a first structure material over a substrate and an anode. The anode is disposed over the substrate. An interlayer dielectric (ILD) material is deposited over the first structure material. An ILD material is patterned. An intermediate structure material is deposited over the ILD material and the first structure material. A second structure material is deposited over the intermediate structure material. A portion of the second structure material is removed to form a second structure. A portion of the intermediate structure material disposed over the ILD material is removed to form an intermediate structure. A portion of the first structure material is removed to form a first structure of an overhang structure. The overhang structure comprises the first structure, the second structure, and the intermediate structure.

### CROSS-REFERENCE TO RELATED APPLICATIONS

This application claims benefit of U.S. provisional patent application Ser. No. 63/516,755, filed Jul. 31, 2023, which is herein incorporated by reference.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits and methods of forming sub-pixel circuits to increase pixel-per-inch and provide improved OLED performance.

### SUMMARY

In one embodiment, a method of forming a device is disclosed. The method includes depositing a first structure material over a substrate and an anode. The anode is disposed over the substrate. An interlayer dielectric (ILD) material is deposited over the first structure material. An ILD material is patterned. An intermediate structure material is deposited over the ILD material and the first structure material. A second structure material is deposited over the intermediate structure material. A portion of the second structure material is removed to form a second structure. A portion of the intermediate structure material disposed over the ILD material is removed to form an intermediate structure. A portion of the first structure material is removed to form a first structure of an overhang structure. The overhang structure comprises the first structure, the second structure, and the intermediate structure.

In another embodiment, a device is disclosed. The device includes a substrate, overhang structures disposed over the substrate, and a plurality of sub-pixels. Each overhang structure includes a first structure, an intermediate structure disposed over the first structure, and a second structure disposed over the intermediate structure. The second structure has an overhang extension extending laterally past the first structure. Each sub-pixel includes an organic light-emitting diode (OLED) material extending under the overhang extension such that the OLED material contacts a sidewall of the first structure under the overhang extension, and a cathode disposed over the OLED material and extending under the overhang extension such that the cathode contacts the sidewall of the first structure under the overhang extension.

In yet another embodiment, a method of forming a device is disclosed. The method includes forming an anode over a substrate and depositing a first structure material over the substrate. An interlayer dielectric (ILD) material is disposed over the first structure material. A first resist is deposited and patterned over the ILD material. A portion of the ILD exposed by the first resist is removed. An intermediate structure material is deposited over the ILD material and the first structure material. A second structure material is deposited over the intermediate structure material. The second structure material is planarized to form a second structure and an intermediate structure. The ILD material is removed. Portions of the first structure material are removed to form a first structure of an overhang structure. The overhang structure comprises the first structure, the second structure, and the intermediate structure. An organic light emitting diode (OLED) material, a cathode, and an encapsulation layer are deposited. A second resist is deposited and patterned in a first sub-pixel. A portion of the OLED material, the cathode, and the encapsulation layer exposed by the second resist are removed. The second resist is removed.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a schematic, cross-sectional view of a sub-pixel circuit, according to embodiments.

FIG. 1B is a schematic, cross-sectional view of a portion of the sub-pixel circuit, according to embodiments.

FIG. 2 is a flow diagram of a method for forming a sub-pixel, according to embodiments.

FIGS. 3A-3O are schematic, cross-sectional views of a substrate during a method of forming a sub-pixel according to embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ advanced overhang structures to improve functionality of the display.

Each of the embodiments described herein of the sub-pixel circuit include a plurality of sub-pixels with each of the sub-pixels defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more subpixels. Each sub-pixel has OLED materials configured to emit a white, red, green, blue or other color light when energized, e.g., the OLED materials of a first sub-pixel emits a red light when energized, the OLED materials of a second sub-pixel emits a green light when energized, and the OLED materials of a third sub-pixel emits a blue light when energized.

The overhangs are permanent to the sub-pixel circuit and include at least a second structure disposed over a first structure. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)) and cathode. In some instances, an encapsulation layer may be disposed via evaporation deposition. In embodiments including one or more capping layers, the capping layers are disposed between the cathode and the encapsulation layer. The overhang structures and the evaporation angle set by the evaporation source define the deposition angles, i.e., the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer of a respective subpixel is disposed over the cathode with the encapsulation layer extending under at least a portion of each of the adjacent overhang structures and along a sidewall of each of the adjacent overhang structures.

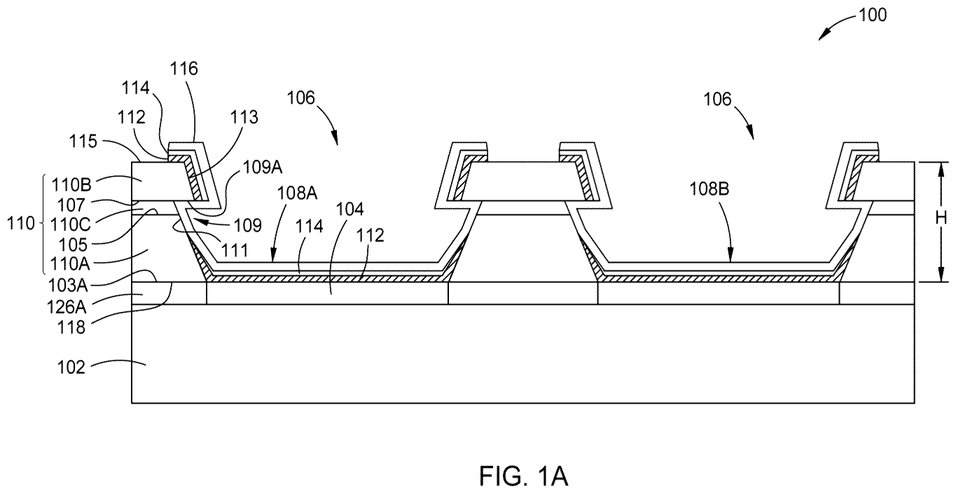

FIG. 1A is a schematic, cross-sectional view of a sub-pixel circuit 100. FIG. 1B is a portion of the schematic, cross-sectional view of a portion of the sub-pixel circuit 100. The sub-pixel circuit 100 includes a substrate 102. Metal-containing layers (e.g., anodes 104) may be patterned on the substrate 102 and are defined by adjacent separation structures 126A disposed on the substrate 102. In one embodiment, which may be combined with other embodiments, the anodes 104 are pre-patterned on the substrate 102. E.g., the substrate 102 is pre-patterned with anodes 104 of indium tin oxide (ITO). The anodes 104 are configured to operate as anodes of respective sub-pixels. In one embodiment, which may be combined with other embodiments, the anode 104 is a layer stack of a first transparent conductive oxide (TCO) layer, a second metal-containing layer disposed on the first TCO layer, and a third TCO layer disposed on the second metal-containing layer. The anodes 104 include, but are not limited to, chromium, titanium, gold, silver, copper, aluminum, ITO, a combination thereof, or other suitably conductive materials.

The separation structures 126A are disposed over the substrate 102. The separation structures 126A include one of an organic material, an organic material with an inorganic coating disposed thereover, or an inorganic material. In some embodiments, which may be combined with other embodiments, the separation structures 126A may be an electrically insulative polymer. The organic material of the separation structures 126A includes, but is not limited to, polyimides. The inorganic material of the separation structures 126A includes, but is not limited to, silicon oxide (SiO₂), silicon nitride (Si₃N₄), silicon oxynitride (Si₂N₂O), magnesium fluoride (MgF₂), or combinations thereof. Adjacent separation structures 126A define a respective sub-pixels and expose the anode 104 of the respective sub-pixel circuit 100.

The sub-pixel circuit 100 has a plurality of sub-pixels 106, including at least a first sub-pixel 108A and second sub-pixel 108B. While FIG. 1 depicts the first sub-pixel 108A and the second sub-pixel 108B, the sub-pixel circuit 100 of the embodiments described herein may include two or more sub-pixels, such as a third sub-pixel and a fourth sub-pixel. Each sub-pixel has OLED materials configured to emit a white, red, green, blue or other color light when energized, e.g., the OLED materials of the first sub-pixel 108A emits a red light when energized, the OLED materials of the second sub-pixel 108B emits a green light when energized, the OLED materials of a third sub-pixel emits a blue light when energized, and the OLED materials of a fourth sub-pixel emits another color light when energized.

Each sub-pixel 106 includes adjacent overhang structures 110, with adjacent sub-pixels sharing the adjacent overhang structures 110. The overhang structures 110 are permanent to the sub-pixel circuit 100. The overhang structures 110 further define each sub-pixel 106 of the sub-pixel circuit 100. Each overhang structure 110 includes adjacent overhangs 109. The adjacent overhangs 109 are defined by an overhang extension 109A of a second structure 110B extending laterally past an upper surface 105 of a first structure 110A. The second structure 110B is disposed over the first structure 110A. The second structure 110B may be disposed on the upper surface 105 of the first structure 110A. The second structure 110B has a thickness less than 1 micron, such as about 100 nm to about 300 nm, such as about 200 nm. A bottom surface 107 of the second structure 110B has a width of about 250 nm to about 750 nm, such as about 500 nm. The overhang extension 109A extends about 50 nm to about 150 nm past an edge of a bottom surface 118 of the first structure 110A. The overhang structures 110 have a height H from the upper surface 103A of the separation structures 126A and the upper surface of the anode 104 of less than about 500 nm.

In some embodiments, which may be combined with other embodiments, the second structure 110B may also be disposed over an intermediate structure 110C. The intermediate structure 110C may be disposed over the upper surface 105 of the first structure 110A. The intermediate structure 110C may be an adhesion promotion material. The adhesion promotion material improves adhesion between the first structure 110A and the second structure 110B. The adhesion promotion material may include a chromium (Cr) material, a titanium material (Ti), or a tantalum nitride material (TaN). The adhesion promotion layer has a thickness of about 10 nm to about 20 nm.

The first structure 110A is disposed over the substrate 102. In some embodiments, which may be combined with other embodiments, the first structure 110A is disposed over an upper surface 103A of the separation structures 126A. The first structure 110A has a thickness of about 100 nm to about 500 nm, such as about 200 nm to about 400 nm, such as about 300 nm.

In one embodiment, which may be combined with other embodiments, the overhang structures 110 include the second structure 110B of a conductive inorganic material and the first structure 110A of a non-conductive inorganic material. In another embodiment, the overhang structures 110 include the first structure 110A and the second structure 110B of a non-conductive inorganic material. The conductive materials include a copper (Cu), aluminum (AI), aluminum neodymium (AlNd), molybdenum (Mo), molybdenum tungsten (MoW), or combinations thereof. The non-conductive materials include amorphous silicon (a-Si), silicon nitride (Si₃N₄), silicon oxide (SiO₂), silicon oxynitride (Si₂N₂O), germanium (Ge), germanium arsenide (GeAs III or IV), or combinations thereof. The overhang structures 110 are able to remain in place, i.e., are permanent.

The adjacent overhangs 109 are defined by the overhang extension 109A. At least the bottom surface 107 of the second structure 110B is wider than the upper surface 105 of the first structure 110A to form the overhang extension 109A. The overhang extension 109A of the second structure 110B forms the overhang 109 and allows for the second structure 110B to shadow the first structure 110A. The shadowing of the overhang 109 provides for evaporation deposition of an OLED material 112 and a cathode 114. The OLED material 112 may include one or more of a HIL, a HTL, an EML, and an ETL. The OLED material 112 is disposed over and in contact with the anode 104. The OLED material 112 is disposed under adjacent overhangs 109 and may contact a sidewall 111 of the first structure 110A. In one embodiment, which may be combined with other embodiments, the OLED material 112 is different from the material of the first structure 110A, the second structure 110B, and the intermediate structure 110C. The cathode 114 is disposed over the OLED material 112 and extends under the adjacent overhangs 109. The cathode 114 may extend past an endpoint of the OLED material 112. The cathode 114 may contact the sidewall 111 of the first structure 110A. The overhang structures 110 and an evaporation angle set by an evaporation source define deposition angles, e.g., the overhang structures provide for a shadowing effect during evaporation deposition with the evaporation angle set by the evaporation source.

The cathode 114 includes a conductive material, such as a metal. E.g., the cathode 114 includes, but is not limited to, silver, magnesium, chromium, titanium, aluminum, ITO, or a combination thereof. In one embodiment, material of the cathode 114 is different from the material of the first structure 110A, the second structure 110B, and intermediate structure 110C. In some embodiments, which may be combined with other embodiments, the OLED material 112 and the cathode 114 are disposed over a sidewall 113 of the second structure 110B of the overhang structures 110. In other embodiments, which may be combined with other embodiments, the OLED material 112 and the cathode 114 are disposed over an upper surface 115 of the second structure 110B of the overhang structures 110. In still other embodiments, which may be combined with other embodiments, the OLED material 112 and the cathode 114 end on the sidewall 111 of the first structure 110A, i.e., are not disposed over the sidewall 113 of the second structure 110B or the upper surface 115 of the second structure 110B.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the overhangs 109 and along a sidewall 111 of each of the first structure 110A and the second structure 110B. The encapsulation layer 116 is disposed over the cathode 114 and extends at least to contact the cathode 114 over the sidewall 111 of the first structure 110A. In some embodiments, which may be combined with other embodiments, the encapsulation layer 116 extends to contact the sidewall 111 of the first structure 110A.

In some embodiments, which may be combined with other embodiments, the encapsulation layer 116 extends to contact the second structure 110B at an underside surface of the overhang extension 109A, the sidewall 113 of the second structure 110B, and the upper surface 115 of the second structure 110B. In some embodiments, which may be combined with other embodiments, the encapsulation layer 116 extends to contact the second structure 110B at an underside surface of the overhang extension 109A and to be disposed over the OLED material 112 and the cathode 114 when the OLED material 112 and the cathode 114 are disposed over the sidewall 113 and upper surface 115 of the second structure 110B. In some embodiments, which may be combined with other embodiments, the encapsulation layer 116 ends at the sidewall 111 of the first structure 110A, i.e., is not disposed over the sidewall 113 of the second structure 110B, the upper surface 115 of the second structure 110B, or the underside surface of the overhang extension 109A of the overhang structures 110. The encapsulation layer 116 includes the non-conductive inorganic material, such as the silicon-containing material. The silicon-containing material may include Si₃N₄ containing materials.

In embodiments including one or more capping layers, which may be combined with other embodiments, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, which may be combined with other embodiments, the sub-pixel circuit 100 further includes at least a global passivation layer disposed over the overhang structure 110 and the encapsulation layer 116. In yet another embodiment, the sub-pixel includes an intermediate passivation layer disposed over the overhang structures 110 of each of the sub-pixels 106, and disposed between the encapsulation layer 116 and the global passivation layer.

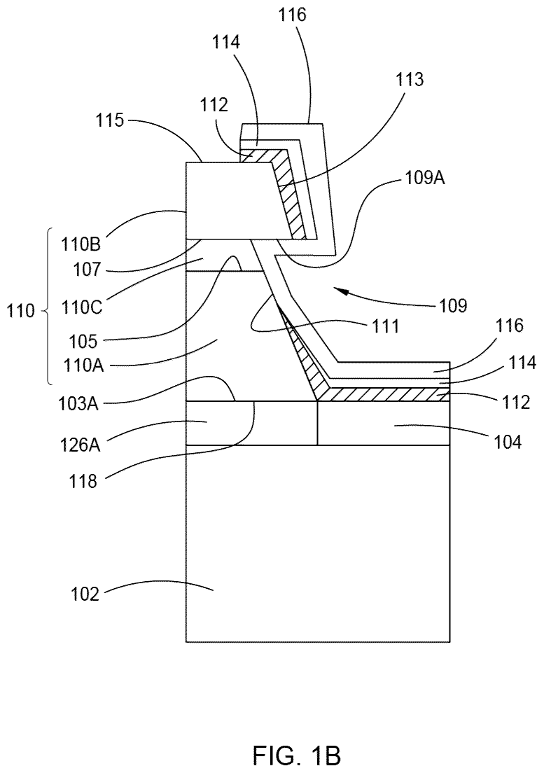

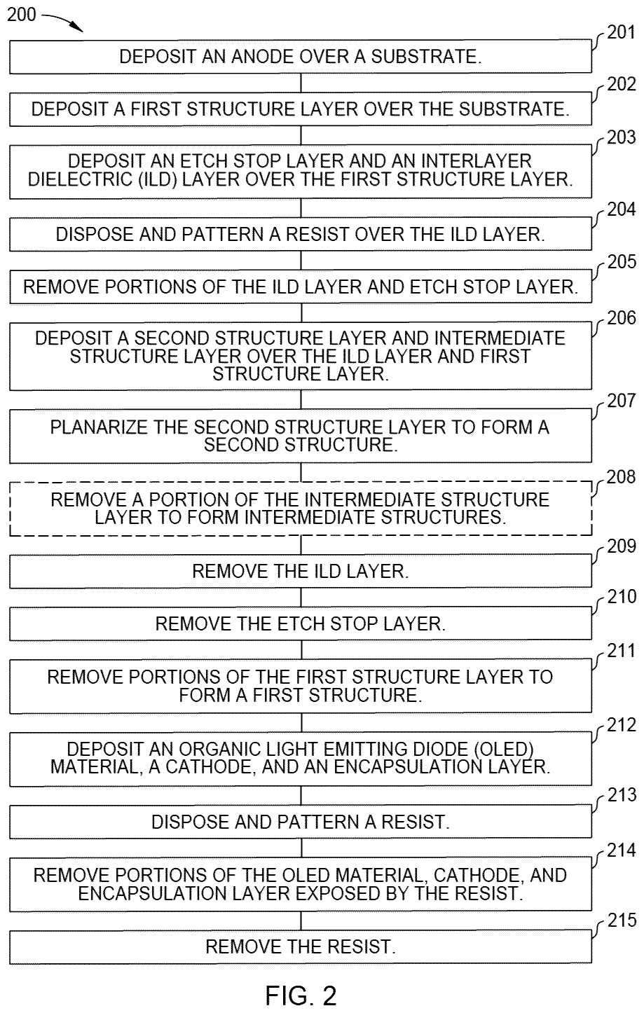

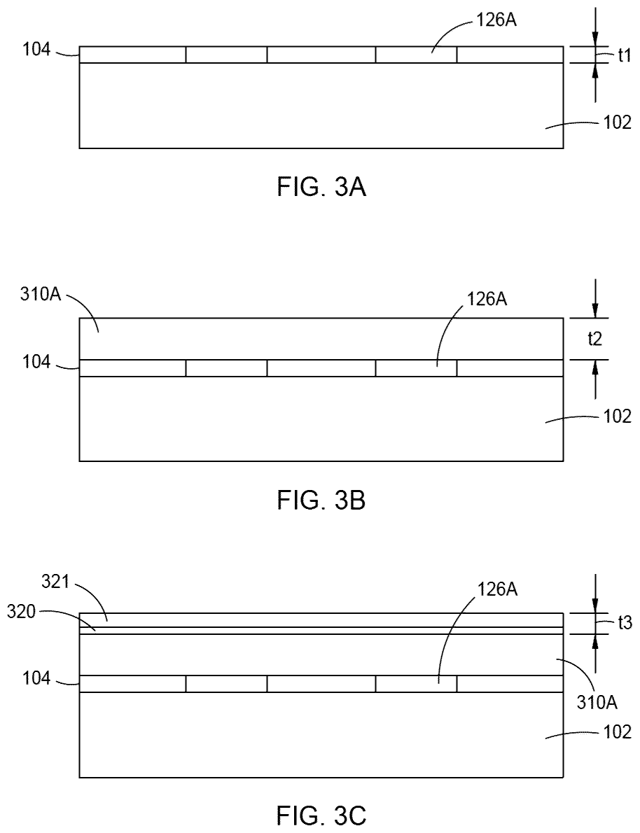

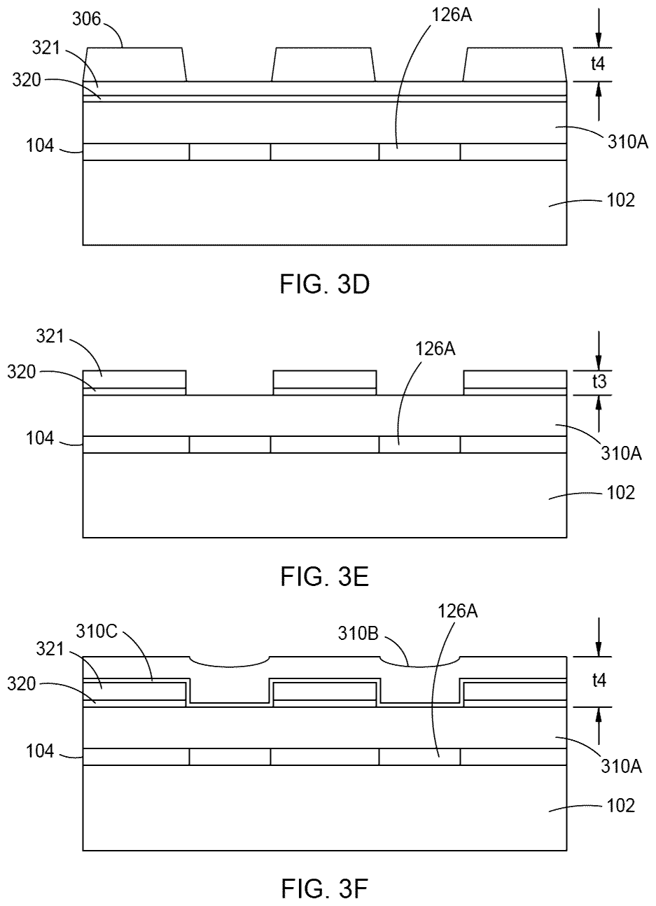

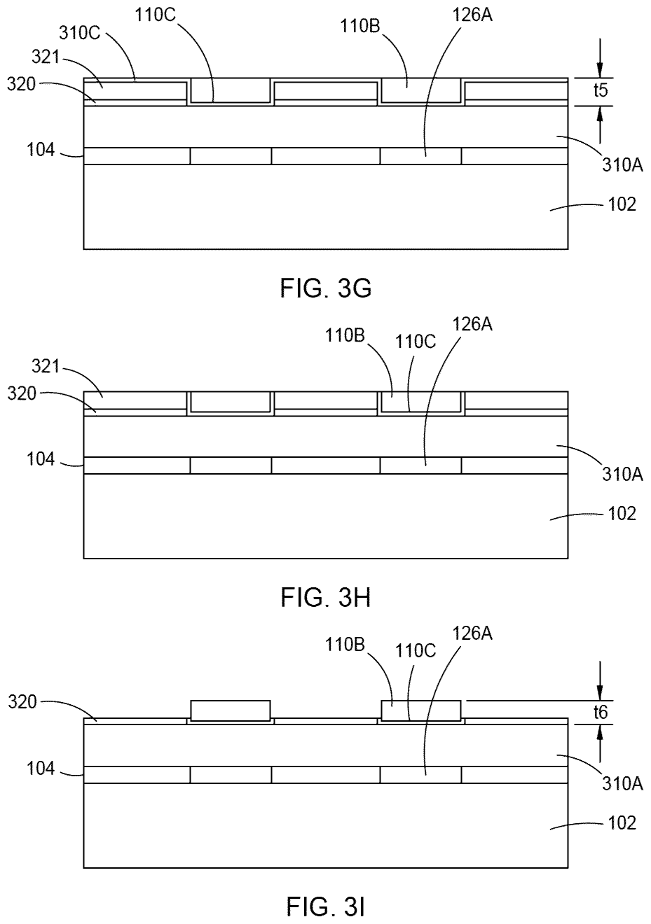

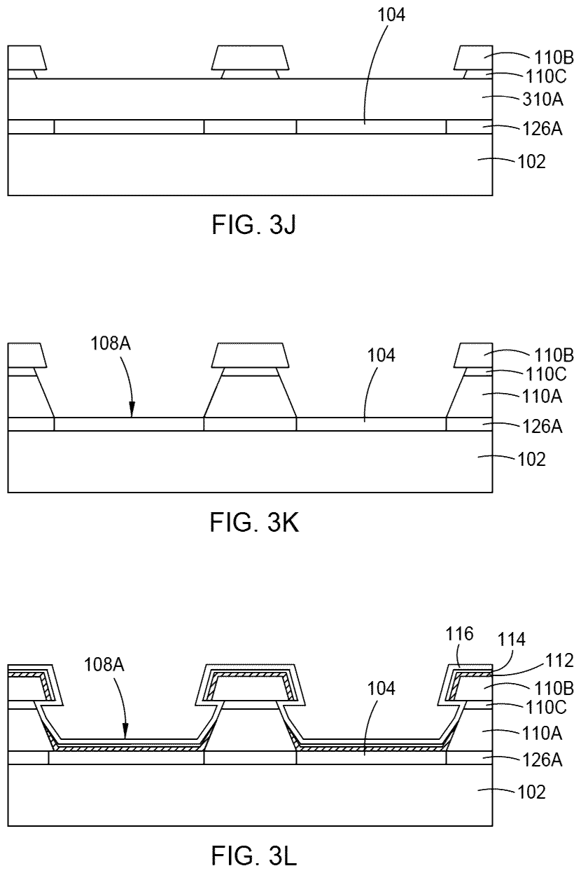

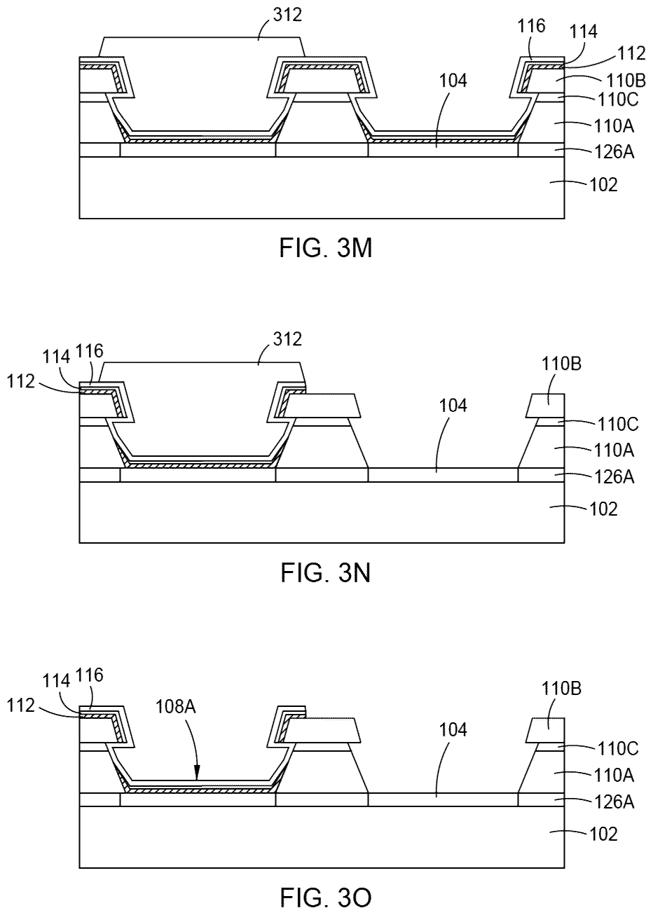

FIG. 2 is a flow diagram of a method 200 for forming a sub-pixel circuit 100 according to embodiment. FIG. 3A-3O are schematic, cross-sectional views of a substrate 102 during a method 200 for forming a sub-pixel circuit 100 according to embodiments described herein.

At operation 201, as shown in FIG. 3A, an anode 104 is deposited over the substrate 102. The anode 104 may be deposited on the substrate 102. The anode 104 may be deposited using metal-organic decomposition (MOD). A plurality of separation structures 126A separates the anode 104 from an adjacent anode 104. The plurality of separation structures 126A are deposited over the substrate 102. The separation structures 126A and anodes 104 are planarized to the same thickness. A thickness t1 from the substrate 102 to an upper surface 103A of the separation structures 126A and anode 104 is from about 200 nm to about 300 nm, such as about 250 nm.

At operation 202, as shown in FIG. 3B, a first structure material 310A is deposited over the substrate 102. The first structure material 310A is deposited on the anode 104 and the separation structures 126A. The first structure material is deposited using chemical vapor deposition (CVD). The first structure material 310A has a thickness t2 from about 100 nm to about 500 nm, such as about 200 nm to about 400 nm, such as about 300 nm. The first structure material 310A includes a non-conductive inorganic material. The non-conductive materials include amorphous silicon (a-Si), silicon nitride (Si₃N₄), silicon oxide (SiO₂), silicon oxynitride (Si₂N₂O), germanium (Ge), germanium arsenide (GeAs III or IV), or combinations thereof.

At operation 203, as shown in FIG. 3C, an etch stop material 320 and an interlayer dielectric (ILD) material 321 are deposited over the first structure material 310A. The etch stop material 320 may be an indium tin oxide (ITO), silicon oxide (SiO₂), aluminum oxide (AlO), silicon nitride (SiN), or combination thereof. The etch stop material may be between about 5 nm and about 50 nm. The ILD material 321 may be a silicon oxide (SiO), a silicon oxynitride (SiON), or a silicon nitride (SiN). A combined thickness t3 of the etch stop material 320 and the ILD material 321 is about 200 nm to about 300 nm, such as about 210 nm.

At operation 204, as shown in FIG. 3D, a resist 306 is disposed and patterned. The resist 306 is disposed over the first structure material 310A. The resist 306 may have a thickness t4 of about 0.8 μm to about 1.2 μm. The resist is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist 306 determines whether the resist is a positive resist or a negative resist. The patterning is one of a photolithography, digital lithography process, or laser ablation process.

At operation 205, as shown in FIG. 3E, portions of the ILD material 321 and etch stop material 320 exposed by the resist 306 are removed. The ILD material 321 and etch stop material 320 are removed by dry etching or wet etching. The dry etching may be performed using a fluorine etch, e.g., using gases SF₆, CF₄, or CHF₃. The wet etching process may be performed using hydrogen fluoride (HF).

At operation 206, as shown in FIG. 3F, a second structure material 310B and an intermediate structure material 310C are deposited over the ILD material 321 and the first structure material 310A. The second structure material 310B may be deposited using sputtering. A thickness t4 from the first structure material 310A to the upper surface of the second structure material 310B may be about 400 nm to about 600 nm. The second structure material 310B includes a conductive material or a non-conductive material. The conductive materials include a copper (Cu), aluminum (AI), aluminum neodymium (AlNd), molybdenum (Mo), molybdenum tungsten (MoW), or combinations thereof. The non-conductive materials include amorphous silicon (a-Si), silicon nitride (Si₃N₄), silicon oxide (SiO₂), silicon oxynitride (Si₂N₂O), germanium (Ge), germanium arsenide (GeAs III or IV), or combinations thereof. The intermediate structure material 310C has a thickness of about 10 nm to about 20 nm. The intermediate structure material includes a chromium (Cr) material, a titanium material (Ti), or a tantalum nitride material (TaN).

At operation 207, as shown in FIG. 3G, the second structure material 310B is planarized to form the second structure 110B. The second structure material 310B is may be planarized using chemical mechanical polishing (CMP). An upper surface of the second structure material 310B and an upper surface of the intermediate structure material 310C may be planarized. A thickness t5 from the first structure material 310A to the upper surface of the intermediate structure material 310C and upper surface of the second structure material 310B may be about 200 nm to about 300 nm. In some embodiments, which may be combined with other embodiments, the CMP process may also remove portions of the intermediate structure material 310C to form the intermediate structure 110C.

At optional operation 208, as shown in FIG. 3H, a portion of the intermediate structure material 310C is removed from a top surface of the ILD material 321 to form an intermediate structure 110C. The intermediate structure material 310C may be removed using dry etching. The dry etching may be performed using a chlorine etch or a fluorine etch. For example, a chlorine etch may be performed for an intermediate structure material 310C including Cr or Ti material, while a chlorine or fluorine etch may be performed for an intermediate structure material 310C including a TaN material. The chlorine etch gases may include Cl₂, BCl₃, CCl₄, or SiCl₄.

At operation 209, as shown in FIG. 3I, the ILD material 321 is removed from the second structure 110B. In some embodiments, the intermediate structure material 310C is removed from sides of the second structure 110B to form the intermediate structure 110C. The ILD material 321 may be removed using dry etching. The dry etching may be performed using SF₆, CF₄, or CHF₃. A thickness t6 from the first structure material 310A to the upper surface of the second structure 110B is about 200 nm to about 250 nm.

At operation 210, as shown in FIG. 3J, the etch stop material 320 is removed. The etch stop material 320 is removed using wet or dry etching. At operation 211, as shown in FIG. 3K, portions of the first structure material 310A exposed by the second structure 110B are removed to form the first structures 110A. The first structure material 310A is removed using dry etching. The etch selectivity between the materials of the second structure material 310B corresponding to the second structure 110B, the first structure material 310A corresponding to the first structure 110A, and the etch processes to remove the exposed portions of the second structure material 310B and the first structure material 310A provide for the bottom surface 107 of the second structure 110B being wider than the upper surface 105 of the first structure 110A to form an overhang extension 109A of the adjacent overhangs 109. The shadowing of the adjacent overhangs 109 provide for evaporation deposition of the OLED material 112 and the cathode 114.

At operation 212, as shown in FIG. 3L, an OLED material 112, a cathode 114, and an encapsulation layer 116 of the first sub-pixel 108A are deposited. The shadowing of the adjacent overhangs 109 provides for evaporation deposition of each of the OLED material 112 and the cathode 114. The total thickness of the OLED material 112 and the cathode 114 is from about 100 nm to about 150 nm. The encapsulation layer 116 is deposited over the cathode 114. A thickness of the encapsulation layer is from about 10 nm to about 50 nm. The shadowing of the adjacent overhangs 109 provides for evaporation deposition of the encapsulation layer 116.

At operation 213, as shown in FIG. 3M, a resist 312 is disposed in the first sub-pixel 108A. The resist 312 is a positive resist or a negative resist. The chemical composition of the resist 312 determine whether the resist 312 is a positive resist or a negative resist. The resist 312 is patterned to protect the first sub-pixel 108A from the subsequent etching processes. The patterning is one of a photolithography, digital lithography process, or laser ablation process.

At operation 214, as shown in FIG. 3N, portions of the OLED material 112, the cathode 114, and the encapsulation layer 116 exposed by the resist 312 are removed. The portions of the OLED material 112, the cathode 114, and the encapsulation layer 116 may be removed using ashing (e.g., O₂ ashing). The surface of the anode 104 may be cleaned using UV ozone (O₃) cleaning.

At operation 215, as shown in FIG. 3O, the resist 312 is removed from the first sub-pixel 108A. Operations 212 to 215 may be repeated until the desired number of sub-pixels are formed.

In summation, sub-pixel circuit includes a substrate. Anodes may be patterned on the substrate and are defined by adjacent separation structures disposed on the substrate. Each sub-pixel includes adjacent overhang structures, with adjacent sub-pixels sharing the adjacent overhang structures. Each overhang structure 110 includes adjacent overhangs. The adjacent overhangs are defined by an overhang extension of a second structure extending laterally past an upper surface of a first structure. The second structure is disposed over the first structure. The overhang structures have a height from the upper surface of the separation structures and the upper surface of the anode of less than about 500 nm. The second structure may also be disposed over an intermediate structure. The intermediate structure improves adhesion between the first structure and the second structure. The intermediate structure has a thickness of about 10 nm to about 20 nm.

While the foregoing is directed to embodiments of the present disclosure, other and further embodiments of the disclosure may be devised without departing from the basic scope thereof, and the scope thereof is determined by the claims that follow.

What is claimed is:

1. A method of forming a device, comprising:
depositing a first structure material over a substrate and an anode, wherein the anode is disposed over the substrate;
depositing an interlayer dielectric (ILD) material over the first structure material;
patterning the ILD material;
depositing an intermediate structure material over the ILD material and the first structure material;
depositing a second structure material over the intermediate structure material;
removing a portion of the second structure material to form a second structure;
removing a portion of the intermediate structure material disposed over the ILD material to form an intermediate structure; and
removing a portion of the first structure material to form a first structure of an overhang structure, wherein the overhang structure comprises the first structure, the second structure, and the intermediate structure.

2. The method of claim 1, wherein the intermediate structure material comprises chromium, titanium, or tantalum nitride.

3. The method of claim 1, further comprising:
depositing an organic light emitting diode (OLED) material, a cathode, and an encapsulation layer in a first sub-pixel, the first sub-pixel defined by adjacent overhang structures;
depositing and patterning a second resist in a first sub-pixel;
removing a portion of the OLED material, the cathode, and the encapsulation layer exposed by the second resist; and
removing the second resist.

4. The method of claim 1, wherein patterning the ILD material comprises:
depositing and patterning a first resist over the ILD material; and
removing a portion of the ILD exposed by the first resist.

5. The method of claim 1, wherein the second structure material comprises at least one of copper, aluminum, aluminum neodymium, molybdenum, and molybdenum tungsten.

6. The method of claim 1, wherein the second structure material comprises an amorphous silicon, titanium, silicon nitride, silicon oxide, silicon oxynitride, germanium, or germanium arsenide.

7. The method of claim 1, wherein the first structure material comprises at least one of amorphous silicon, titanium, silicon nitride, silicon oxide, silicon oxynitride, germanium, and germanium arsenide.

8. The method of claim 1, wherein the intermediate structure has a thickness of about 10 nm to about 20 nm.

9. The method of claim 1, wherein the second structure has a thickness of about 100 nm to about 300 nm.

10. The method of claim 1, wherein the first structure has a thickness of about 200 nm to about 400 nm.

11. A device, comprising:
a substrate;
overhang structures disposed over the substrate, each overhang structure:
a first structure;
an intermediate structure disposed over the first structure; and
a second structure disposed over the intermediate structure, the second structure having an overhang extension extending laterally past the first structure;
a plurality of sub-pixels, each sub-pixel comprising:
an organic light-emitting diode (OLED) material extending under the overhang extension such that the OLED material contacts a sidewall of the first structure under the overhang extension; and
a cathode disposed over the OLED material and extending under the overhang extension such that the cathode contacts the sidewall of the first structure under the overhang extension.

12. The device of claim 11, wherein the intermediate structure comprises chromium, titanium, or tantalum nitride.

13. The device of claim 11, wherein the first structure comprises an amorphous silicon, titanium, silicon nitride, silicon oxide, silicon oxynitride, germanium, or germanium arsenide.

14. The device of claim 11, wherein the second structure comprises amorphous silicon, titanium, silicon nitride, silicon oxide, silicon oxynitride, germanium, or germanium arsenide.

15. The device of claim 11, wherein the second structure comprises copper, aluminum, aluminum neodymium, molybdenum, or molybdenum tungsten.

16. The device of claim 11, wherein the intermediate structure has a thickness of about 10 nm to about 20 nm.

17. The device of claim 11, wherein the second structure has a thickness of about 100 nm to about 300 nm.

18. The device of claim 11, wherein the first structure has a thickness of about 200 nm to about 400 nm.

19. A method of forming a device, comprising:
forming an anode over a substrate;
depositing a first structure material over the substrate;
depositing an interlayer dielectric (ILD) material over the first structure material;
depositing and patterning a first resist over the ILD material;
removing a portion of the ILD exposed by the first resist;
depositing an intermediate structure material over the ILD material and the first structure material;
depositing second structure material over the intermediate structure material;
planarizing the second structure material to form a second structure and an intermediate structure;
removing the ILD material;
removing portions of the first structure material to form a first structure of an overhang structure, wherein the overhang structure comprises the first structure, the second structure, and the intermediate structure;
depositing an organic light emitting diode (OLED) material, a cathode, and an encapsulation layer;
depositing and patterning a second resist in a first sub-pixel;
removing a portion of the OLED material, the cathode, and the encapsulation layer exposed by the second resist; and
removing the second resist.

20. The method of claim 19, wherein:
the intermediate structure has a thickness of about 10 nm to about 20 nm;
the second structure has a thickness of about 100 nm to about 300 nm; and
the first structure has a thickness of about 200 nm to about 400 nm.
